(19) United States
(12) Patent Application Publication
(10) Pub. No.: US 2002/0075969 A1
(43) Pub. Date: Jun. 20, 2002

(54) Apparatus and method for bit disparity detection

(76) Inventors: Warren Sande, Kanata (CA); Lucian A. Agapie, Kanata (CA); Matthew D. Brown, Kinburn (CA)

Correspondence Address: SMART & BIGGAR, P.O. BOX 2999, STATION D, 55 METCALFE STREET, SUITE 900, OTTAWA, ON, K1P5Y6, CA

(21) Appl. No.: 09/739,897

(22) Filed: Dec. 20, 2000

(51) Int. Cl. H04L 25/34; H03D 1/00; H04L 25/49; H04L 27/06

(52) U.S. Cl. 375/292; 375/340

(57) ABSTRACT

A bit disparity monitor is disclosed in which a data stream is sub-sampled and logical 1's are detected in the sub-sampled stream. Within a predetermined period, the number of logical 1's is counted and the ratio of logical 1's to the number of bits is determined and compared to acceptable thresholds of bit disparity. In a second embodiment, the data stream is inverted and both the original data stream and the inverted data stream are sampled. The number of logical 1's detected in the sub-sampled original data stream and the number of logical 0's in the sub-sampled inverted data stream are correlated and mismatches, indicative of a transitional sample, are discarded before the bit disparity ratio is determined. Methods of comparing the bit disparity of a data stream to an acceptable threshold are also disclosed.

### FIELD OF THE INVENTION

This invention relates to communications networks and in particular to an improved apparatus and method for bit disparity detection in optical communications networks.

### BACKGROUND OF THE INVENTION

High bits (1's) and low bits (0's) within a data stream are preferably equal in number over a set period of time. Bit disparity is a condition whereby the balance of 1's and 0's in a signal deviates from a 1:1 ratio. Over a sufficiently large period of time it is expected that the number of 1's sent will be equal to the number of 0's sent, that is, the 1's density in a signal will be 50%. Non-compliant bit disparity refers to a situation in which the bit disparity exceeds an acceptable threshold, either because of an unacceptably high or low 1's density.

There are a number of reasons that high bit disparity can occur.

First, there are a number of data protocols which have been identified to have reasonable potential to exhibit non-compliant bit disparity, including 100Base-FX, a physical layer standard of Fast Ethernet, and FDDI (Fibre Distributed Data Interface), which are both encoded with 4B/5B coding and NRZI. 4B/5B coding is a method of line coding which translates each set of 4 bits into a corresponding set of 5 bits. NRZI (Non-return-to-zero inverted) is a coding which causes the output to transition on a ‘1’ and not transition on a ‘0’. The combination of 4B/5B and NRZI is intended to provide sufficient scrambling (density of 0-1 and 1-0 transitions) and disparity control to make the signal suitable for optical transmission. However, there are some data patterns that still exhibit non-ideal 1's density, even after 4B/5B and NRZI coding. The codes are such that some codes may exhibit 1's density of 40% or 60%. If such like codes persist, the average 1's density may approach the acceptable limits of bit disparity. While either protocol carrying real traffic is not expected to exhibit this condition, test patterns may do so and the possibility always exists that real traffic will exhibit this condition as well.

Similarly, digitized video signals (D1 video) can contain patterns consisting of concatenated code words containing 19 0's and a single 1, resulting in a 1's density of 5%.

Second, it is possible that a compliant data signal may be degraded by the hardware of the optical network, or the link between the customer and the network, such that the bit disparity exceeds acceptable limits. While rare, such occurrences frequently involve failed components or connections.

When bit disparity is non-compliant, the integrity of the data passing through an AC-coupled system will be degraded, resulting in bit errors or false alarm signals. This degraded signal performance may be manifested in a number of ways.

First, AC coupling between functional blocks in the high speed path of an optical network cannot support signals exhibiting persistent non-compliant bit disparity and may, in an extreme case, result in single or even multiple bit errors.

Second, while the optical system of the lasers used in an optical network is designed to accommodate a certain amount of power variation, high bit disparity may cause a power variation in excess of the acceptable threshold, resulting in bit errors on the affected channel. Further, the biasing of the laser may be affected such that the laser produces side modes in adjacent channels, resulting in bit errors in these channels as well.

Third, the difference between the laser output power and the expected power is frequently monitored as an equipment alarm condition. Where the 1's density is high, the output power may appear to change sufficiently to incorrectly trigger this alarm condition.

Fourth, a fluctuation in the mean power of any of the wavelengths traversing an optical amplifier will cause amplitude modulation of other wavelengths traversing the same amplifier. The effect is most pronounced if the fluctuation wavelength is high in power relative to the total optical power entering the amplifier. A variation in the bit disparity affects directly and almost linearly the mean optical power of a signal. Accordingly, minimizing bit disparity will help to mitigate this amplitude modulation effect.

Therefore, if bit disparity could be monitored, one would adjust thresholds and raise alarms. Additionally, a network could warn the user that good performance cannot be guaranteed, because of high bit disparity in the incoming data.

There are some data protocols which are designed to provide balanced signals, that is, signals with little or no bit disparity. Examples include SONET, which is scrambled using a pseudo-random bit sequence XOR'ed with the raw data, and 8B/10B coding, in which very tight disparity control was part of the coding design. When such signals are used, there is no need for a bit disparity monitor. However, many factors govern the choice of a data protocol, and low bit disparity is not typically one of significance to the customer, who chooses the data protocol to be used. Many data protocols presently used in optical communications were originally intended to be carried in the electrical domain, where bit disparity is of little or no significance.

One possible implementation for bit disparity detection is to demultiplex the signal and reduce the transmission rate to one at which the high and low bits could be counted and compared. This requires more circuitry and processing than can be justified merely for this purpose.

An analog implementation for bit disparity monitoring contemplates the use of a low pass filter to find the mean power of the data stream. If there is low bit disparity, the mean power will lie directly between the power of the high and low bits. Such an approach has been useful to provide a feedback parameter into the laser driver control loop to adjust the laser parameters, without actually monitoring the bit disparity. One problem with this implementation is that the time period over which the bit disparity is determined is fixed dependent upon the bandwidth of the low pass filter utilized. Further, such an implementation requires the use of an A/D converter to determine an actual value for the bit disparity, if the actual value is required.

### SUMMARY OF THE INVENTION

Accordingly, embodiments of the present invention provide an apparatus and method for bit disparity detection.

In a first embodiment of the present invention, samples of the data stream are obtained and each sample is interpreted as a 1 or a 0. The total number of 1's so sampled over a time period is determined and statistical analysis is applied to determine a bit disparity value for the time period under consideration. The time period can be adjusted by adjusting the number of samples that are considered. The sample rate may be at a lower rate than the transmission rate.

In a second embodiment of the present invention, the accuracy of the bit disparity determination is improved by discarding samples of transitions between 1's and 0's. In this embodiment, both the data stream and its inverse are simultaneously sampled. If the data stream is in transition at the point of sampling, the samples from the data stream and the inverted data stream may be the same and such samples are discarded. The remaining sample points are totalled and statistical analysis is applied to determine the bit disparity value for the time period under consideration. Again, the time period can be adjusted by adjusting the number of samples that are considered.

According to a broad aspect of an embodiment of the present invention, there is disclosed a method of determining whether the bit disparity in a data stream is acceptable, comprising the steps of: sampling the data stream, detecting the number of samples of the data stream which have a predetermined one of two logical values within a time period, calculating the ratio of samples detected to have the predetermined logical value to the number of samples considered, and comparing the calculated ratio with a predetermined acceptable threshold.

According to a second broad aspect, the invention provides a method of determining whether the bit disparity in a data stream is acceptable, comprising the steps of: generating an inverted data stream which is the time-synchronous logical inverse of the data stream, simultaneously sampling the data stream and the inverted data stream, detecting the number of samples of the data stream which have a predetermined one of two logical values within a time period, detecting the number of samples of the inverted data stream which have a different predetermined logical value within the same time period, correlating the detected samples of the data stream with the detected samples of the inverted data stream, discarding those samples of the data stream which are detected in which the corresponding samples of the inverted data stream are not also detected; calculating the ratio of the remaining samples in one of the data streams detected to have the corresponding predetermined logical value to the number of samples considered but not discarded, and comparing the calculated ratio with a predetermined acceptable threshold.

According to a third broad aspect, the invention provides a bit disparity monitor for monitoring the bit disparity of a data stream comprising: a sub-sampler for sub-sampling the data stream; a detector for identifying the number of samples of the data stream which have a predetermined one of two logical values within a time period; a calculator for determining the ratio of samples detected by the detector to have the corresponding predetermined logical value to the number of samples considered; and a comparator for comparing the ratio with a predetermined acceptable threshold.

According to a fourth broad aspect, the invention provides a bit disparity monitor for monitoring the bit disparity of a data stream comprising: a sub-sampler for sub-sampling the data stream; a 1's detector coupled to the sub-sampler for identifying those samples of the data stream which have a logical value of one; a 1's counter coupled to the 1's detector for determining the number of identified samples within a time period; a samples counter for determining the number of samples within the time period; a clock generator coupled to the sub-sampler for indicating when a sample should be taken and coupled to the samples counter for indicating when a sample was taken; a timer coupled to the 1's counter and the samples counter for indicating the start and end of the time period; a comparator coupled to the 1's counter and the samples counter for comparing the number of identified samples with the total number of samples taken within the time period; and a memory element coupled to the comparator for storing the comparison results for monitoring.

According to a fifth broad aspect, the invention provides a bit disparity monitor for monitoring the disparity of a data stream comprising: an inverter for generating an inverted data stream which is the time-synchronous logical inverse of the data stream; a sub-sampler for simultaneously sub-sampling the data stream and the inverted data stream; a first detector for identifying the number of samples of the data stream which have a predetermined one of several logical values within a time period; a second detector for identifying the number of samples of the inverted data stream which have a different predetermined logical value within the same time period; a correlator for correlating the samples detected by the first and second detectors and discarding those samples detected by the first detector in which the corresponding sample is not also detected by the second detector; a calculator for determining the ratio of remaining samples detected by one of the detectors to have the corresponding predetermined logical value to the number of samples considered but not discarded; and a comparator for comparing the ratio with a predetermined acceptable threshold.

According to a sixth broad aspect, the invention provides a bit disparity monitor for monitoring the bit disparity of a data stream comprising: an inverter for generating an inverted data stream which is the time-synchronous logical inverse of the data stream; a first sub-sampler for sub-sampling the data stream; a second sub-sampler for sub-sampling the inverted data stream; a 1's detector coupled to the first sub-sampler for identifying those samples of the data stream which have a logical value of one; a 0's detector coupled to the second sub-sampler for identifying those samples of the inverted data stream which have a logical value of zero; a samples counter for determining the number of samples within the time period; a correlator coupled to the 1's detector, the 0's detector and the samples counter for correlating the samples identified by the 0's detector and discarding those samples which are not identified by both the 1's detector and the 0's detector; a 1's counter coupled to the correlator for determining the number of remaining identified samples within a time period; a clock generator coupled to the first and second sub-samplers for indicating when a sample should be taken and coupled to the samples counter for indicating when a sample was taken; a timer coupled to the 1's counter and the samples counter for indicating the start and end of the time period; a comparator coupled to the 1's counter and the samples counter for comparing the number of identified samples with the total number of samples taken within the time period; and a memory element coupled to the comparator for storing the comparison results for monitoring.

According to a seventh broad aspect, the invention provides a computer-readable medium for storing computer-executable instructions which, when executed by a processor in a bit disparity monitor corresponding to a data stream to: sample the data stream, detect the number of samples of the data stream which have a predetermined one of a plurality of logical values within a time period, calculate the ratio of samples detected to have the predetermined logical value to the number of samples considered, and compare the calculated ratio with a predetermined acceptable threshold.

According to an eighth broad aspect, the invention provides a computer-readable medium for storing computer-executable instructions which, when executed by a processor in a bit disparity monitor corresponding to a data stream to: generate an inverted data stream which is the time-synchronous logical inverse of the data stream, simultaneously sample the data stream and the inverted data stream, detect the number of samples of the data stream which have a predetermined one of several logical values within a time period, detect the number of samples of the inverted data stream which have a different predetermined logical value within the same time period, correlate the detected samples of the data stream with the detected samples of the inverted data stream, discard those samples of the data stream which are detected in which the corresponding samples of the inverted data stream are not also detected; calculate the ratio of the remaining samples in one of the data streams detected to have the corresponding predetermined logical value to the number of samples considered but not discarded, and compare the calculated ratio with a predetermined acceptable threshold.

### BRIEF DESCRIPTION OF THE DRAWINGS

The embodiments of the present invention will now be described by reference to the following figures, in which identical reference numerals in different figures indicate identical elements and in which:

FIG. 1 is a block diagram of a bit disparity monitor in accordance with a first embodiment of the present invention;

FIG. 2 is a logic flow diagram of the processing performed by the bit disparity monitor of FIG. 1; and

FIG. 3 is a block diagram of a bit disparity monitor in accordance with a second embodiment of the present invention.

### DETAILED DESCRIPTION OF THE PREFERRED EMBODIMENTS

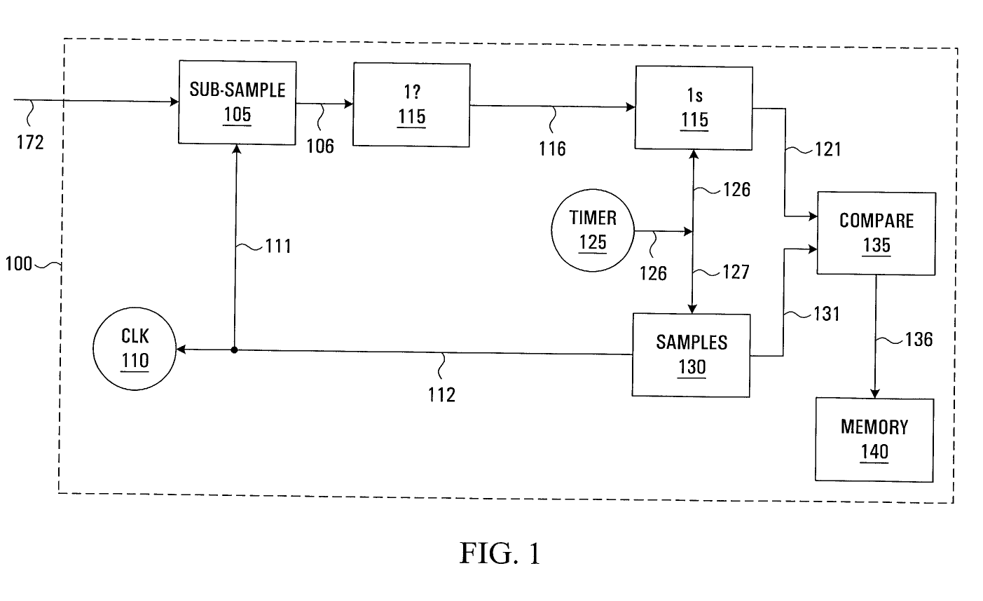

Referring now to FIG. 1, a first embodiment of a bit disparity monitor 100 is shown in detail. The bit disparity monitor 100 may be a component of an optical transmitter which may form part of a node in an optical network such as SONET or a WDM system. The bit disparity monitor 100 comprises a sub-sampler 105, a clock generator 110, a 1's detector 115, a 1's counter 120, a timer 125, a samples counter 130, a comparator 135 and a memory 140.

The sub-sampler 105 accepts as input an electrical signal received by the transmitter (not shown) with which the bit disparity monitor 100 is associated along an electrical data transmission line 172 and a clock signal from the clock generator 110 along control line 111. The electrical signal received along transmission line 172 is the signal which is to be converted to an optical signal by the transmitter (not shown), and may typically have a data rate in the range between 50 MHz and 2 GHz.

The sub-sampler 105 outputs a sub-sampled data stream of the input signal along control line 106 to the 1's detector 115. The input signal is sub-sampled at each instance of the clock signal received from the clock generator 110.

The clock generator 110 generates the clock signal along control line 111 to the sub-sampler 105 and along control line 112 to the samples counter 130. While in a preferred embodiment, the clock rate is 50 MHz, any convenient low speed clock rate may be used.

The clock signal is used by the sub-sampler 105 to sub-sample the input signal and by the samples counter 130 to count the number of samples that have been sub-sampled by the sub-sampler 105.

The 1's detector 115 accepts the sub-sampled data stream from the sub-sampler 105 along control line 106. It determines whether each datum in the data stream is a 1 or a 0. Where the datum is determined to be a 1, the 1's detector 115 generates a signal along control line 116 to the 1's counter 120. Where the datum is determined to be a 0, no signal is generated.

The timer 125 also generates a periodic timer signal at a rate which is lower than the clock rate and transmits it along control line 126 to the 1's detector 115 and along control line 127 to the samples counter 130. In a preferred embodiment, it in fact generates periodic timer signals upon expiry of the timer at a plurality of periods, typically a low, medium and long time period.

The clock rate and the timer rate will determine the number of samples of data considered by the bit disparity monitor and the corresponding accuracy and elasticity of the empirical determination of the bit disparity by this apparatus. Thus, the bit disparity determined using the low time period timer signal will be highly elastic but likely less accurate than the bit disparity determined using the long time period signal.

The 1's counter 120 counts the number of signals received by it from the 1's detector 115 along control line 116, each indicative of a 1 having been detected by the 1's detector 115 in the sub-sampled data stream. The 1's counter 120 is also connected to the timer 125 along control line 126. Periodic timer signals are received upon expiry of the timer 125 along control line 126 by the 1's counter 120. Upon receipt of one of the timer signals, the 1's counter communicates the total number of 1's counted by it since the last instance of the same timer signal to the comparator 135. This may be accomplished by subtracting from the current total the total obtained at the last instance of the same timer signal, or alternatively, by resetting its registers corresponding to that timer signal at each instance of the timer signal.

The samples counter 130 receives as input both the clock signal generated by the clock generator 110 along control line 112 and the timer signal(s) generated by the timer 125 along control line 127. The samples counter 130 counts the number of periods of the clock signal which is representative of the number of samples that have been sub-sampled by the sub-sampler 105. Upon receipt of one of the timer signals, the samples counter 130 communicates the total number of clock pulses (corresponding to the number of samples) counted by it since the last instance of the same timer signal to the comparator 135. This may be accomplished by subtracting from the current total the total obtained at the last instance of the same timer signal, or alternatively, by resetting its registers corresponding to that timer signal at each instance of the timer signal.

The comparator 135 receives as input, data from the 1's counter 120 along control line 121 and from the samples counter 130 along control line 131 on a periodic basis corresponding to each of the timer signal rates. The data received from the 1's counter 120 is a count of the number of 1's detected by the 1's detector 115 within the corresponding timer period from the 1's counter 120. The data received from the samples counter 130 is a count of the number of clock pulses detected during the same time period by the samples counter 130, which corresponds to the number of samples considered by the 1's detector 115. The comparator 135 uses this data to generate a figure of merit for the bit disparity of the optical domain signal being sub-sampled and outputs this figure of merit to a memory element 140 along control line 136.

Because the comparison is of samples rather than bits, the figure of merit is necessarily a statistical approximation of the actual bit disparity, whose accuracy is dependent on the sub-sampling rate chosen and the input data rate. Those persons having ordinary skill in this art will readily recognize that the control line 136 is figurative only and may comprise a data and control bus system of the type conventionally found in microprocessor systems.

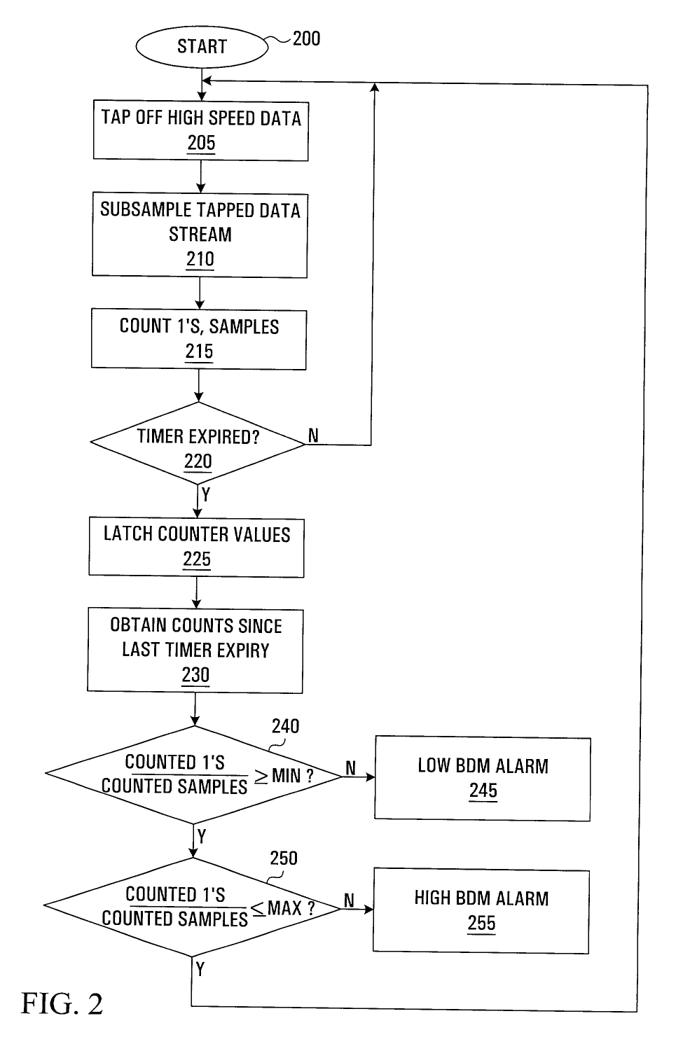

Turning now to FIG. 2, a logical flow chart showing the processing performed by the bit disparity monitor 100.

Upon startup 200, the bit disparity monitor 100 taps off the high speed data stream 205, which it then subsamples 210.

The bit disparity monitor 100 then counts the number of 1's detected in the sub-sampled data stream, as well as the number of bits in the sub-sampled data stream 215.

The bit disparity monitor 100 thereafter determines whether one of the timers has expired. If not, it reverts to the start 200. If so, it causes the counter values corresponding to the timer which expired to be latched 225.

From the latched values, the bit disparity monitor 100 obtains the counts for bits and detected 1's since the last expiry of the corresponding timer 230.

The bit disparity monitor 100 thereafter compares the ratio of the number of detected 1's to the number of samples with a minimum threshold value 240. The minimum threshold value will be chosen taking into account the timer period to which it corresponds. Generally, the minimum threshold for shorter timer periods will be lower than the corresponding threshold for longer timer periods, since the optical system will tolerate poorer bit disparity performance over shorter time periods.

If the ratio is less than the minimum threshold, a low BDM (Bit Disparity Monitor) alarm is generated to the OAM (Operations, Administration, Maintenance) system for the network 245. Such an alarm generation mechanism is known in the art and need not be described herein.

If the ratio exceeds the minimum threshold, the bit disparity monitor 100 compares the ratio of the number of detected 1's to the number of samples with a maximum threshold value 250. The maximum threshold value will be chosen taking into account the timer period to which it corresponds. Generally, the maximum threshold for shorter timer periods will be greater than the corresponding threshold for longer timer periods, since the optical system will tolerate poorer bit disparity performance over shorter time periods.

If the ratio exceeds the maximum threshold, a high BDM alarm is generated to the OAM system for the network 255, again in known fashion. Otherwise, the processing reverts to the start 200.

The use of a sub-sampler having a lower clock rate than the data rate 105, while permitting the bit disparity calculation to be more easily implemented and accomplished in real-time, introduces the possibility of a mismatch between the sub-sampler frequency and phase and frequency and phase of the input signal being sub-sampled, such that at the time of sub-sampling, the input signal is in a bit transition, which depending upon the value attached to the sample, may skew inappropriately the bit disparity figure of merit.

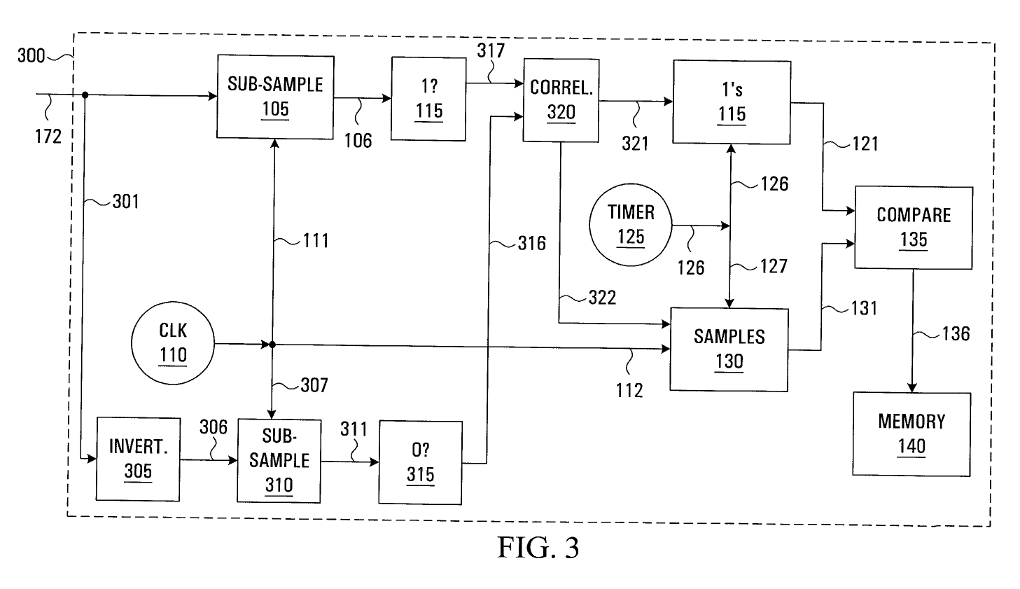

A second embodiment of the present invention is shown in FIG. 3, which overcomes this problem at the cost of slightly greater complexity. Those persons having ordinary skill in this art will readily recognize that the logical processing shown in FIG. 2 can be easily adapted to describe the processing for the bit disparity monitor 300 of the second embodiment.

As will be seen from a comparison of FIGS. 1 and 3, the bit disparity monitor 300 includes all of the elements of the bit disparity monitor 100, namely the sub-sampler 105, the clock generator 110, the 1's detector 115, the 1's counter 120, the timer 125, the samples counter 130, the comparator 135 and the memory 140, albeit in a slightly different configuration. In addition, the bit disparity monitor 300 further comprises a signal inverter 305, a inverted data sub-sampler 310, a 0's detector 315 and a correlator 320.

The signal inverter 305 receives as input the signal along transmission line 301, which taps off transmission line 172. It generates as output an inverted data signal which it outputs to the inverted data sub-sampler 310 along transmission line 306. This representation of the signal inverter 305 is functional only. Those persons having ordinary skill in the art will readily recognize that in fact, a differential version of the single ended data stream must be generated, namely the data stream and its time-synchronous logical inverse. Otherwise, as discussed below, the bit transitions of the data stream and its inverse would not line up.

The inverted data sub-sampler 310 accepts as input the inverted signal generated by the signal inverter 305 along transmission line 306 and a clock signal from the clock generator 110 along control line 307. It outputs a sub-sampled data stream of the input inverted signal along control line 211 to the 0's detector 215. The input inverted signal is sub-sampled at each instance of the clock signal received from the clock generator 110, which drives the sub-sampling of the non-inverted signal by the sub-sampler 105.

The 0's detector 315 accepts the sub-sampled data stream from the inverted sub-sampler 310 along control line 311. It determines whether each datum in the data stream is a 1 or a 0. Where the datum is determined to be a 0, the 0's detector 315 generates a signal along control line 316 to the correlator 320. Where the datum is determined to be a 1, no signal is generated.

The correlator 320 is interposed between the 1's detector 115 and the 1's counter 120. This is the only change in configuration in respect of the elements of the bit disparity monitor 300 which are also present in the bit disparity monitor 100. The correlator 320 accepts as input the signals generated by the 1's detector 115 along control line 317 and the signals generated by the 0's detector 315 along control line 316. The correlator 320 generates an output to the 1's counter 120 along control line 321 and to the samples counter 130 along control line 322.

As its name indicates, the correlator 320 correlates corresponding samples from the 1's detector 115 and the 0's detector 315 and discards samples in which a sample is detected by the 1's detector 115 but not by the 0's detector 315 or vice versa.

Where detection by the 1's detector 115 is signaled by a logical 1 value, detection by the 0's detector 315 is signaled by a logical 0 value and a positive correlation is signaled by a logical 1 value, the correlator 320 effectively performs an Exclusive-Or logical function. That is, there the input signals are different, the correlator 320 generates a signal along control line 322 to the samples counter 130, and where the samples are different and the 1's detector 115 detects a 1 value, the correlator 320 generates a signal along control line 321 to the 1's counter 120 and a signal along control line 322 to the samples counter 130.

The use of the correlator 320 in the bit disparity monitor 300 permits the exclusion of sub-samples which are taken while the data stream is in a transition, which is manifested by both the optical data stream and its inverse being read as the same logical state, whether a 1 or a 0.

The remaining elements of the bit disparity monitor 300 are identical in configuration and function to their counterparts in the bit disparity monitor 100.

The present invention can be implemented in digital electronic circuitry, or in computer hardware, firmware, software, or in combination thereof. Apparatus of the invention can be implemented in a computer program product tangibly embodied in a machine-readable storage device for execution by a programmable processor; and methods actions can be performed by a programmable processor executing a program of instructions to perform functions of the invention by operating on input data and generating output. The invention can be implemented advantageously in one or more computer programs that are executable on a programmable system including at least one input device, and at least one output device. Each computer program can be implemented in a high-level procedural or object oriented programming language, or in assembly or machine language if desired; and in any case, the language can be a compiled or interpreted language. Suitable processors include, by way of example, both general and specific microprocessors. Generally, a processor will receive instructions and data from a read-only memory and/or a random access memory. Generally, a computer will include one or more mass storage devices for storing data files; such devices include magnetic disks, such as internal hard disks and removable disks; magneto-optical disks; and optical disks. Storage devices suitable for tangibly embodying computer program instructions and data include all forms of non-volatile memory, including by way of example semiconductor memory devices, such as EPROM, EEPROM, and flash memory devices; magnetic disks such as internal hard disks and removable disks; magneto-optical disks; and CD-ROM disks. Any of the foregoing can be supplemented by, or incorporated in ASICs (application-specific integrated circuits).

Examples of such types of computers are programmable processing systems contained in the bit disparity monitor 100 or 300 suitable for implementing or performing the apparatus or methods of the invention. The system may comprise a processor, a random access memory, a hard drive controller, and an input/output controller coupled by a processor bus.

It will be apparent to those skilled in this art that various modifications and variations may be made to the embodiments disclosed herein, consistent with the present invention, without departing from the spirit and scope of the present invention.

For example, instead of using a timer as the trigger for comparing the 1's counter and the samples counter, one could use a certain number of samples (i.e. a certain value of the samples counter) as the trigger.

Other embodiments consistent with the present invention will become apparent from consideration of the specification and the practice of the invention disclosed therein.

Accordingly, the specification and the embodiments are to be considered exemplary only, with a true scope and spirit of the invention being disclosed by the following claims.

We claim:

1. A method of determining whether the bit disparity in a data stream is acceptable, comprising the steps of:
sampling the data stream,
detecting the number of samples of the data stream which have a predetermined one of two logical values within a time period,
calculating the ratio of samples detected to have the predetermined logical value to the number of samples considered, and
comparing the calculated ratio with a predetermined acceptable threshold.

2. A method of determining whether the bit disparity in a data stream is acceptable, comprising the steps of:
generating an inverted data stream which is the time-synchronous logical inverse of the data stream,
simultaneously sampling the data stream and the inverted data stream,
detecting the number of samples of the data stream which have a predetermined one of two logical values within a time period,
detecting the number of samples of the inverted data stream which have a different predetermined logical value within the same time period,
correlating the detected samples of the data stream with the detected samples of the inverted data stream,
discarding those samples of the data stream which are detected in which the corresponding samples of the inverted data stream are not also detected;
calculating the ratio of the remaining samples in one of the data streams detected to have the corresponding predetermined logical value to the number of samples considered but not discarded, and
comparing the calculated ratio with a predetermined acceptable threshold.

3. A bit disparity monitor for monitoring the bit disparity of a data stream comprising:
a sub-sampler for sub-sampling the data stream;
a detector for identifying the number of samples of the data stream which have a predetermined one of two logical values within a time period;
a calculator for determining the ratio of samples detected by the detector to have the corresponding predetermined logical value to the number of samples considered; and
a comparator for comparing the ratio with a predetermined acceptable threshold.

4. A bit disparity monitor according to claim 3 in which the detector identifies samples having a value of logical one.

5. A bit disparity monitor according to claim 3 in which the sub-sampler samples at a rate of 50 MHz.

6. A transmitter for transmitting a data stream along a communication link, comprising the bit disparity monitor of claim 3.

7. A node for connection with a communications link along which the node may transmit a data stream, comprising the bit disparity monitor of claim 3.

8. A communications network comprising nodes interconnected by communications links along which data streams are transmitted and received, comprising the bit disparity monitor of claim 3.

9. A bit disparity monitor for monitoring the bit disparity of a data stream comprising:
a sub-sampler for sub-sampling the data stream;
a 1's detector coupled to the sub-sampler for identifying those samples of the data stream which have a logical value of one;
a 1's counter coupled to the 1's detector for determining the number of identified samples within a time period;
a samples counter for determining the number of samples within the time period;
a clock generator coupled to the sub-sampler for indicating when a sample should be taken and coupled to the samples counter for indicating when a sample was taken;
a timer coupled to the 1's counter and the samples counter for indicating the start and end of the time period;
a comparator coupled to the 1's counter and the samples counter for comparing the number of identified samples with the total number of samples taken within the time period; and
a memory element coupled to the comparator for storing the comparison results for monitoring.

10. A bit disparity monitor for monitoring the disparity of a data stream comprising:
an inverter for generating an inverted data stream which is the time-synchronous logical inverse of the data stream;
a sub-sampler for simultaneously sub-sampling the data stream and the inverted data stream;
a first detector for identifying the number of samples of the data stream which have a predetermined one of several logical values within a time period;
a second detector for identifying the number of samples of the inverted data stream which have a different predetermined logical value within the same time period;
a correlator for correlating the samples detected by the first and second detectors and discarding those samples detected by the first detector in which the corresponding sample is not also detected by the second detector;
a calculator for determining the ratio of remaining samples detected by one of the detectors to have the corresponding predetermined logical value to the number of samples considered but not discarded; and
a comparator for comparing the ratio with a predetermined acceptable threshold.

11. A bit disparity monitor according to claim 10 in which the first detector identifies samples having a value of logical one.

12. A bit disparity monitor according to claim 10 in which the second detector identifies samples having a value of logical zero.

13. A bit disparity monitor for monitoring the bit disparity of a data stream comprising:
an inverter for generating an inverted data stream which is the time-synchronous logical inverse of the data stream;
a first sub-sampler for sub-sampling the data stream;
a second sub-sampler for sub-sampling the inverted data stream;
a 1's detector coupled to the first sub-sampler for identifying those samples of the data stream which have a logical value of one;
a 0's detector coupled to the second sub-sampler for identifying those samples of the inverted data stream which have a logical value of zero;
a samples counter for determining the number of samples within the time period;
a correlator coupled to the 1's detector, the 0's detector and the samples counter for correlating the samples identified by the 0's detector and discarding those samples which are not identified by both the 1's detector and the 0's detector;
a 1's counter coupled to the correlator for determining the number of remaining identified samples within a time period;
a clock generator coupled to the first and second sub-samplers for indicating when a sample should be taken and coupled to the samples counter for indicating when a sample was taken;
a timer coupled to the 1's counter and the samples counter for indicating the start and end of the time period;
a comparator coupled to the 1's counter and the samples counter for comparing the number of identified samples with the total number of samples taken within the time period; and
a memory element coupled to the comparator for storing the comparison results for monitoring.

14. A computer-readable medium for storing computer-executable instructions which, when executed by a processor in a bit disparity monitor corresponding to a data stream to:
sample the data stream,
detect the number of samples of the data stream which have a predetermined one of a plurality of logical values within a time period,
calculate the ratio of samples detected to have the predetermined logical value to the number of samples considered, and
compare the calculated ratio with a predetermined acceptable threshold.

15. A computer-readable medium for storing computer-executable instructions which, when executed by a processor in a bit disparity monitor corresponding to a data stream to:
generate an inverted data stream which is the time-synchronous logical inverse of the data stream,
simultaneously sample the data stream and the inverted data stream,
detect the number of samples of the data stream which have a predetermined one of several logical values within a time period,
detect the number of samples of the inverted data stream which have a different predetermined logical value within the same time period,
correlate the detected samples of the data stream with the detected samples of the inverted data stream,
discard those samples of the data stream which are detected in which the corresponding samples of the inverted data stream are not also detected;
calculate the ratio of the remaining samples in one of the data streams detected to have the corresponding predetermined logical value to the number of samples considered but not discarded, and
compare the calculated ratio with a predetermined acceptable threshold.
